(19) United States
(12) Patent Application Publication
(10) Pub. No.: US 2007/0205389 A1
(43) Pub. Date: Sep. 6, 2007

(54) Titanium-Containing Perovskite Compound and Production Method Thereof

(75) Inventors: Tadatoshi Kurozumi, Chiba (JP); Akihiko Shirakawa, Chiba (JP); Jun Tanaka, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Showa Denko K.K., Tokyo (JP)

(21) Appl. No.: 10/593,832

(22) PCT Filed: Mar. 24, 2005
(86) PCT No.: PCT/JP05/06219

§ 371 Date: Nov. 21, 2006

Related U.S. Application Data
(60) Provisional application No. 60/557,420, filed on Mar. 30, 2004.

(30) Foreign Application Priority Data
Mar. 25, 2004 (JP) 2004-089328

(51) Int. Cl. H01L 41/18; C04B 35/00; C04B 35/495; H01L 41/187; C01G 23/00

(52) U.S. Cl. 252/62.9 R; 423/598; 501/136; 501/134

(57) ABSTRACT

The present invention relates to a method for producing a titanium-containing perovskite compound, characterized in that the method comprises a step of reacting titanium oxide produced through a vapor-phase method with at least one element selected from a group of alkaline earth metal compound and Pb compound in an alkaline solution; a perovskite compound obtained by the method; and electronic materials and the like using the compound. The titanium-containing perovskite compound obtained by the method in the present invention has a small particle diameter and few impurities, is excellent in electric characteristics, and enables to make the size of electronic devices smaller since the compound can be shaped in a thin film product.

### CROSS REFERENCE TO THE RELATED APPLICATIONS

This is an application filed pursuant to 35 U.S.C. Section 111(a) with claiming the benefit of U.S. Provisional application Ser. No. 60/557,420 filed Mar. 30, 2004 under the provision of 35 U.S.C. Section 111(b), pursuant to 35 U.S.C. Section 119(e)(1).

### TECHNICAL FIELD

The present invention relates to a titanium-containing perovskite compound, particularly to a titanium-containing perovskite compound employed as, for example, an electronic material such as dielectric material, piezoelectric material, pyroelectric material, a laminated ceramic capacitor, a capacitor built in a substrate, a film capacitor or a thin-film material, and to a production method of the compound.

### BACKGROUND ART

Titanium-containing perovskite compounds such as barium titanate are widely employed as functional materials such as dielectric material, piezoelectric material and pyroelectric material, since the compounds exhibit excellent electric characteristics such as dielectric characteristics, piezoelectric characteristics and pyroelectric characteristics. The perovskite compounds are employed as a variety of materials for capacitors such as a laminated ceramic capacitor and a capacitor built in a substrate as well as used for dielectric filters, dielectric antennas, dielectric oscillators, dielectric duplexers, capacitors, phase-shifters, laminated piezoelectric actuators, etc.

A titanium-containing perovskite compound is employed as an electronic material for such as a thin-film product or a ceramic material, after undergoing the steps such as mixing with a solvent to provide a slurry or a paste of the compound; molding and sintering; and forming a sheet or forming a composite with resin. In recent years, electronic components have become increasingly smaller, lightweight, high-performance and of higher signal frequency. To keep pace with these trends, there is rising demand for development of a particulate titanium-containing perovskite compound or the like having a small particle diameter and exhibiting excellent electric characteristics in terms of dielectric constant and the like.

However, it is considerably difficult to reduce the particle diameter of the titanium-containing perovskite compound while maintaining a high dielectric property of the compound. In the case of barium titanate, the particle diameter of a barium titanate having a high content of barium titanate of tetragonal form, which is known to exhibit ferroelectricity and excellent electric characteristics such as high dielectric constant, cannot be sufficiently reduced. Since the tetragonal form content of a barium titanate having a small particle diameter cannot be increased, the compound exhibits paraelectric properties and fails to attain a sufficiently high dielectric constant.

Production methods of barium titanate particles include solid phase method comprising mixing raw material powders of an oxide and/or a carbonate by use of a ball mill or the like and allowing the mixture to react at a high temperature of about 800° C. or higher; oxalic acid method comprising preparing an oxalic acid composite salt and thermally decomposing the salt to thereby obtain barium titanate particles; hydrothermal synthesis comprising allowing raw materials to react in an aqueous solvent under high temperature and high pressure to thereby obtain a precursor; and alkoxide method comprising hydrolyzing metal alkoxides serving as raw materials to thereby obtain a precursor. Examples further include a method in which a hydrolyzate of a titanium compound is reacted with an aqueous barium in a strong alkaline medium (see, for example, Japanese Patent No. 1841875); a method in which titanium oxide sol is reacted with a barium compound in a strong alkaline aqueous solution (see, for example, WO 00/35811 (EP1148030)); a method in which titanium oxide sol is reacted with a barium compound in a sealed vessel (see, for example, Japanese Laid-Open Patent Publication (kokai) No. 7-291607); and a method comprising reacting titanium oxide sol with a barium compound in an alkaline solution in the presence of a basic compound, removing the basic compound as a gas after completion of reaction, and calcining (see, for example, WO 03/004416 (EP1415955). There has been proposed another method comprising preparing a high-barium-concentration basic solution by dissolving barium in water of an amount corresponding to crystallization water, adding thereto titanium oxide micropowder having a large specific area to thereby form a multi-component oxide powder at comparatively low temperature, and firing (calcining) the powder at 900° C. or higher, to thereby form tetragonal barium titanate (see Japanese Laid-Open Patent Publication (kokai) No. 2003-252623).

According to the solid phase method, barium titanate having no defects and exhibiting excellent electric characteristics can be obtained at low cost. However, the thus-formed barium titanate has a large particle diameter, which is not suited for an electronic material assuming the form of a small-size thin film or the like.

According to the oxalic acid method, the obtained barium titanate contains a carbonate group originating from oxalic acid, although the barium titanate has a particle diameter smaller than that of the particulate barium titanate produced through the solid phase method. In addition, a hydroxyl group originating from water incorporated into the barium titanate remains. Therefore, the obtained barium titanate exhibits poor electric characteristics.

Fine barium titanate particles can be produced through the hydrothermal synthesis method or the alkoxide method, but there remains a large amount of hydroxyl groups originating from water incorporated into inside of the barium titanate particles. Although the hydroxyl groups can be removed through heating, heating generates pores inside the particles. Therefore, barium titanate exhibiting excellent electric characteristics is difficult to produce. When the alkoxide method is employed, carbonate groups remains in barium titanate. Moreover, the hydrothermal synthesis method requires a specifically designed apparatus for performing under high temperature and high pressure, which leads to a problem of raising production cost.

The methods described in Japanese Patent No. 1841875 and WO 00/35811 (EP1148030) require a water-washing step. During this step, barium is dissolved in water, and the formed hydroxide is incorporated into the barium titanate as hydroxyl groups. Although the hydroxyl groups can be removed through heating, heating generates pores inside the particles. Therefore, barium titanate exhibiting excellent electric characteristics is difficult to produce. In the method described in Japanese Laid-Open Patent Publication (kokai) No. 7-291607, materials are reacted under heating and stirring in the presence of a pulverization medium in a sealed vessel. Therefore, specifically designed apparatus is required, which leads to a problem of raising production cost.

The method described in Japanese Laid-Open Patent Publication (kokai) No. 2003-252623 employs a high-barium-concentration basic solution prepared by dissolving barium in water of an amount corresponding to crystallization water. The reaction takes place in a highly viscous slurry and from the viewpoint of reaction rate, TiO₂ powder having a specific surface area as large as 250 m²/g or more must be used. The composite oxide produced from the slurry-mediated reaction is a cubic crystal. Converting the oxide crystals from cubic to tetragonal, which exhibits ferroelectricity, requires a step of calcined at 900° C. or higher. Through such calcining, the particle diameter of the product increases (specifically, reaches a size about six times or more that before calcining).

### DISCLOSURE OF THE INVENTION

An object of the present invention is to provide a method for producing a titanium-containing perovskite compound of a small particle diameter, which contains less unwanted impurity and exhibits excellent electric characteristics, for forming thin-film products such as dielectric ceramic thin film, dielectric film, and dielectric coating required for producing a small-size capacitor that enables size reduction of electronic devices. Other objects of the invention are to provide a titanium-containing perovskite compound produced through the method and to provide an electronic device employing the compound.

The present inventors have carried out extensive studies in order to attain the aforementioned objects, and have found that a titanium-containing perovskite compound which has a primary particle diameter approximately equal to that of titanium oxide serving as a starting material and exhibits excellent electric characteristics including ferroelectricity can be produced by reacting, in an alkaline solution in the presence of a basic compound, at least one element selected from a group of alkaline earth metal compound and Pb compound with titanium oxide produced through a vapor-phase method serving as at least one titanium material and, after completion of the reaction, removing the basic compound along with gas. The present invention has been accomplished on the basis of this finding.

Accordingly, the present invention provides a method for producing a titanium-containing perovskite compound, a perovskite compound produced by the method and an electronic material and the like using the compound, as described below, as preferred embodiments.

1. A method for producing a titanium-containing perovskite compound, characterized in that the method comprises a step of reacting titanium oxide produced through a vapor-phase method with at least one element selected from a group of alkaline earth metal compound and Pb compound in an alkaline solution.

2. The method for producing a titanium-containing perovskite compound as described in 1 above, wherein primary particles of the titanium-containing perovskite compound have a diameter (D1) that is 50 to 200% the size of primary particles of the titanium oxide serving as a starting material, the size (D1) being determined by converting the specific surface area (S) of the particles obtained by the BET method to the total surface area of spheres in accordance with the following equation (1):
D1=6/ρS (1)
wherein ρ represents a density of the particles and S represents a BET specific surface area.

3. The method for producing a titanium-containing perovskite compound as described in 1 or 2 above, using ultrafine particles of titanium oxide having a BET specific surface area of 3 to 200 m²/g.

4. The method for producing a titanium-containing perovskite compound as described in any one of 1 to 3 above, using the titanium oxide produced by oxidizing titanium tetrachloride at high temperature by use of an oxidizing gas.

5. The method for producing a titanium-containing perovskite compound as described in 4 above, using the titanium oxide produced by a vapor-phase method is produced by respectively introducing a titanium tetrachloride-containing gas and an oxidizing gas which are heated in advance to 500° C. or higher into a reaction tube at a flow rate of 10 m/sec or more.

6. The method for producing a titanium-containing perovskite compound as described in 5 above, using the titanium oxide produced by retaining the titanium tetrachloride-containing gas and the oxidizing gas in the reaction tube for reaction for one second or shorter under a high-temperature condition higher than 600° C.

7. The method for producing a titanium-containing perovskite compound as described in 6 above, using the titanium oxide produced under a condition of an average gas flow rate in the reaction tube of 5 m/sec or more.

8. The method for producing a titanium-containing perovskite compound as described in any of 4 to 7 above, using the titanium oxide produced by a vapor-phase method is produced by introducing the preheated titanium tetrachloride-containing gas and oxidizing gas into the reaction tube in such a manner that turbulence is generated in the reaction tube.

9. The method for producing a titanium-containing perovskite compound as described in any of 4 to 8 above, using the titanium oxide produced by introducing the titanium tetrachloride-containing gas and the oxidizing gas into the reaction tube through a coaxial parallel flow nozzle and the inner tube of the coaxial parallel flow nozzle has an inside diameter of 50 mm or less.

10. The method for producing a titanium-containing perovskite compound as described in any of 4 to 9 above, wherein the titanium-tetrachloride-containing gas has a titanium tetrachloride content of 10 to 100%.

11. The method for producing a titanium-containing perovskite compound as described in any of 4 to 10 above, wherein each of the titanium tetrachloride-containing gas and the oxidizing gas is heated in advance at 800° C. or higher.

12. The method for producing a titanium-containing perovskite compound as described in any of 1 to 11 above, wherein the titanium oxide produced by a vapor-phase method has a mean particle diameter at a 90% cumulative weight on the particle size distribution curve (D₉₀) of 2.2 μm or less.

13. The method for producing a titanium-containing perovskite compound as described in any of 1 to 12 above, wherein the titanium oxide produced through a vapor-phase method has a distribution constant n, as calculated from the following Rosin-Rammler equation (2), of 1.7 or more:
R=100 exp(−bDⁿ) (2)
wherein D is a particle diameter; R is the percentage of the number of particles larger than D (particle diameter) with respect to the total number of particles; n is a distribution constant; and b is a reciprocal of particle characteristic constant.

14. The method for producing a titanium-containing perovskite compound as described in any of 1 to 13 above, wherein the titanium oxide produced by a vapor-phase method contains anatase-crystal-form titanium oxide.

15. The method for producing a titanium-containing perovskite compound as described in 1 above, using an alkaline solution in which a basic compound exists.

16. The method for producing a titanium-containing perovskite compound as described in 15 above, wherein the basic compound is selected from ammonium, organic amine and hydroxide of ammonium salt.

17. A titanium-containing perovskite compound, which is produced by a method as described in any of 1 to 16 above.

18. The titanium-containing perovskite compound exhibiting ferroelectricity as described in 17 above.

19. A dielectric material containing a titanium-containing perovskite compound as described in 18 above.

20. A paste containing a titanium-containing perovskite compound as described in 18 above.

21. A slurry containing a titanium-containing perovskite compound as described in 18 above.

22. A thin-film product containing a titanium-containing perovskite compound as described in 18 above.

23. A dielectric ceramics containing a titanium-containing perovskite compound as described in 18 above.

24. A pyroelectric ceramics containing a titanium-containing perovskite compound as described in 18 above.

25. A piezoelectric ceramics containing a titanium-containing perovskite compound as described in 18 above.

26. A capacitor containing a dielectric ceramics as described in 23 above.

27. An electronic device containing at least one member selected from the group consisting of a thin film product, ceramics and a capacitor as described in any one of 22 to 26 above.

28. A sensor containing one or more members of a thin film product or ceramics as described in any one of 22 to 26 above.

29. A dielectric film employing a titanium-containing perovskite compound as described in 18 above.

30. A capacitor employing a dielectric film as described in 29 above.

31. A ferroelectric memory employing a titanium-containing perovskite compound as described in 18 above.

32. A capacitor built in a substrate, which capacitor employs a titanium-containing perovskite compound as described in 18 above.

### BRIEF DESCRIPTION OF THE DRAWINGS

FIG. 1 is a schematic cross sectional view showing an example of laminated ceramic capacitors as one of the preferable embodiments of the present invention.

FIG. 2 is a diagrammatic view showing an internal structure of a mobile phone provided with the laminated ceramic capacitor in FIG. 1.

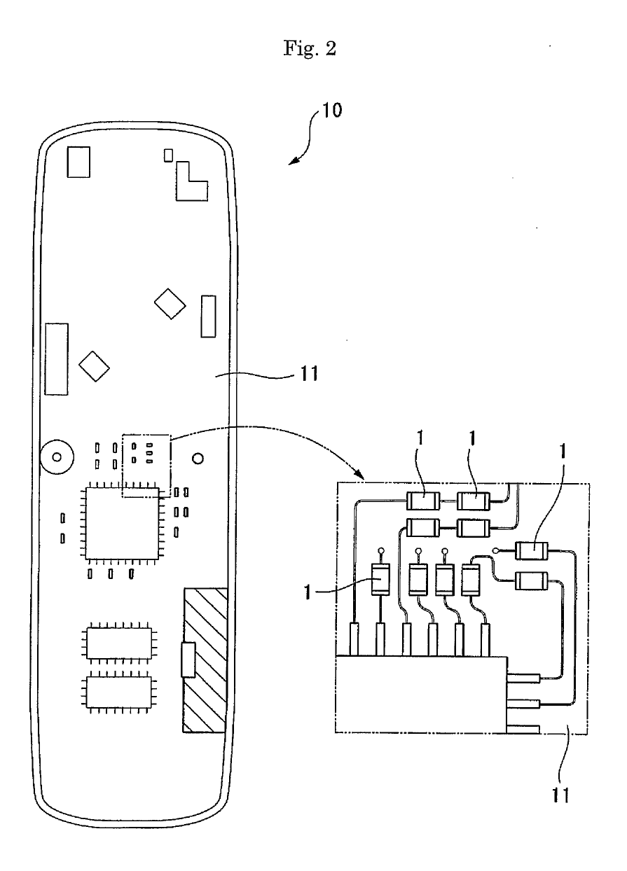

FIG. 3 is an SEM (scanning electron microscope) photograph of a barium titanate obtained in Example 2 in the present invention.

Embodiments of the titanium-containing perovskite compound and the method for producing the compound according to the present invention will next be described in detail.

(I) Titanium-Containing Perovskite Compound

The titanium-containing perovskite compound in the present invention is represented by the formula ABO₃, wherein site A predominantly comprises an alkaline earth metal or Pb, and site B consists of Ti. Pure barium titanate (BaTiO₃), wherein site A and site B consist of Ba and Ti respectively, undergoes phase transition from tetragonal to cubic crystals at about 130° C. In the titanium-containing perovskite compound in the present invention, site A atoms may be partially substituted by a metallic element other than Ba, so long as ferroelectricity through the same phase transition can be attained.

Generally, the phase transition temperature can be arbitrarily regulated by addition of a so-called shifter such as Ca, Mg, Sr, Pb, Si, Fe, Zr, La, Sb or Be. The phase transition temperature of a titanium-containing perovskite compound is also known to vary depending on an impurity having migrated into raw materials or a reaction mixture during production. Therefore, though site A of the titanium-containing perovskite compound in the present invention predominantly comprises an alkaine earth metal or Pb, it may be partially substituted by Ca, Mg, Sr, Pb, Si, Fe, Zr, La, Sb, Be or an impurity (e.g., an alkali metal element) having migrated into raw materials or a reaction mixture during production.

No particular limitation is imposed on the amount of the above metallic elements, so long as the perovskite compound produced by the below-described method exhibits ferroelectricity. BaTiO₃ (metallic elements being Ba and Ti) It is known that pure barium titanate in the tetragonal crystal form exhibits ferroelectricity, while that in the cubic crystal form does not. Thus, the compound in the present invention preferably contains the above metallic elements in such amounts that the compound exhibits ferroelectricity in the similar way as the pure barium titanate. The ferroelectricity of barium titanate is detected on the basis of an endothermic peak at about 130° C. (elevated from room temperature) and an exothermic peak at about 130° C. (cooled from heated temperature) as measured by use of a differential scanning colorimeter. The total peak area at about 130° C. may serve as an index for magnitude of ferroelectricity.

Thus, a titanium-containing perovskite compound according to embodiments of the present invention is characterized in that the compound is produced by a wet-synthesis method and, preferably, particles of the compound exhibit ferroelectricity. In addition, a titanium-containing perovskite compound according to the embodiments of the present invention is characterized in that the compound is in the form of fine powder, which comprises fine particles having a primary particle diameter virtually equivalent to that of titanium oxide particles serving as a starting material. Specifically, the compound is characterized in that the particles of the produced titanium-containing perovskite compound have a primary particle diameter (calculated from the specific surface area of the particles by converting it to the total surface area of true spheres) that is 50 to 200% the size of the primary particles of the titanium oxide serving as a starting material, preferably 60 to 135%, more preferably 70 to 120%. The primary particle diameter is obtained in accordance with the following equation:
D1=6/ρS (1)
wherein ρ represents a density of the particles and S represents a BET specific surface area of the particles. Since the starting material and the product have virtually the same primary particle diameter, material design is facilitated. Incorporation of functional groups such as hydroxyl groups into the titanium-containing perovskite compound substantially does not occur. The titanium-containing perovskite compound in the present invention is characterized in that the compound exhibits high heat resistance and excellent dispersibility.

Heat resistance of the titanium-containing perovskite compound may be determined by means of a thermo-mechanical analyzer. Specifically, barium titanate is kneaded with a binder and press-molded, thereby forming pellets. Each pellet is heated at 20° C./min, and compressibility of the pellet during heating from room temperature to 1,100° C. is measured.

As used herein, the term “dispersibility” refers to such a property that the relevant particles are dispersed in an appropriate solvent in the production of an electronic part using titanium-containing perovskite compound particles. Upon dispersal of the particles, the titanium-containing perovskite compound may be crushed by an appropriate dry or wet method.

As mentioned above, the titanium-containing perovskite compound in the present invention has a small particle diameter and exhibits excellent dispersibility and electric characteristics in terms of dielectric constant and the like. By using a thin-film product such as dielectric ceramics, a dielectric film or a dielectric coating is produced from the particles of the compound as a dielectric material for producing an electronic part, a small-size electronic part such as a capacitor in a substrate or a laminated ceramic capacitor can be produced. Furthermore, when the electronic part is employed in an electronic device, the size and weight of the electronic apparatus can be reduced.

(II) A Method for Producing a Titanium-Containing Perovskite Compound

A production method according to the present invention is a method for producing a titanium-containing perovskite compound exhibiting ferroelectricity, characterized in that the method includes a step of reacting vapor-grown titanium oxide with an alkaline earth metal compound in an alkaline solution in the presence of a basic compound to obtain a titanium-containing perovskite compound. According to the method in the present invention, a titanium-containing perovskite compound exhibiting ferroelectricity can be produced even without a calcining step.

No particular limitation is imposed on the primary particle diameter of the titanium oxide produced by a vapor-phase method, which titanium oxide is employed in the present invention (detailed description will be given below). The primary particle diameter is 7 to 500 nm, preferably 10 to 200 nm, more preferably 15 to 100 nm. Herein, the primary particle diameter is determined as a particle diameter (as calculated from the specific surface area of the particles assuming that each particle is a true sphere) in accordance with the above-described equation (1).

No particular limitation is imposed on the type of the titanium oxide produced by a vapor-phase method, which titanium oxide is employed in the present invention (hereinafter may be abbreviated as vapor-grown titanium oxide). However, titanium oxide including anatase or brookite crystals is preferred. So long as anatase crystals are contained in titanium oxide, it may contain anatase crystal singly or rutil crystal as well. When titanium oxide contains rutile titanium oxide, no particular limitation is imposed on the content of anatase titanium oxide, and the content is generally 1 to 100 mass %, preferably 20 to 100 mass %, more preferably 50 to 100 mass %. This is because, as compared with rutile titanium oxide, anatase titanium oxide is more readily reacted with an alkaline earth metal compound.

No particular limitation is imposed on the method for producing vapor-grown titanium oxide. For example, titanium tetrachloride is oxidized using an oxidizing gas such as oxygen or steam under the reaction conditions of about 1,000° C., whereby fine particles of titanium oxide are produced. Examples of preferred modes of reaction include a production method disclosed in WO01/16027 (EP1231186). The method for producing titanium oxide serving as a starting material in the present invention will next be described in more detail.

The mechanism of growing particles in the vapor phase process is roughly classified into two types. One is CVD (chemical vapor deposition) and another is the growth by collision (coalescence) and sintering of particles. In either case, the growth time must be short so as to obtain ultrafine particulate titanium oxide, which is an object of the present invention. More specifically, in the former growth method, growth may be suppressed by elevating the preliminary heating temperature to thereby increase the chemical reactivity (reaction rate). In the latter growth method, cooling, dilution or the like is swiftly performed to the particulates after completion of CVD, to thereby make the high-temperature residence time at a high temperature as short as possible, so that the growth by sintering and the like can be suppressed.

In the vapor phase method where titanium oxide is produced by oxidizing a titanium tetrachloride-containing gas with an oxidizing gas at a high temperature, preliminary heating of the titanium tetrachloride-containing gas and the oxidizing gas each at 500° C. or higher can suppress CVD growth so that fine particles of titanium oxide having a BET specific surface area of 3 to 200 m²/g can be obtained.

The starting material gas containing titanium tetrachloride preferably has a titanium tetrachloride in a concentration of 10 to 100%, more preferably 20 to 100%. By using a gas having a titanium tetrachloride concentration of 10% or higher, a large number of uniform nuclei are generated and also reactivity increases, so that particles grown under CVD-control can be hardly formed and particles having a narrow particle size distribution can be obtained.

The gas for diluting titanium tetrachloride in the titanium tetrachloride-containing gas is selected from those non-reactive with titanium tetrachloride and also incapable of being oxidized. Specific examples of the preferred diluting gas include nitrogen and argon.

The titanium tetrachloride-containing gas and the oxidizing gas must be preliminarily heated at 500° C. or higher, preferably 800° C. or higher.

When the preliminary heating temperature is lower than 500° C., generation of uniform nuclei is reduced and reactivity becomes low, so that the resulting particles will have a broad particle size distribution.

The titanium tetrachloride-containing gas and the oxidizing gas are preferably introduced into a reaction tube at respective flow rates of 10 m/sec or more. By increasing the flow rates, mixing of two gases is promoted. When the temperature at the introduction of gases into a reaction tube is 500° C. or higher, reaction is completed at the same time with the mixing, so that the generation of uniform nuclei can be promoted and the zone where particles grown under the CVD-control are formed can be narrowed.

It is preferable to introduce the starting material gas into a reaction tube so as to thoroughly mix the gases introduced into the reaction tube. So long as the gases are thoroughly mixed, the fluid state of gas within the reaction tube is not particularly limited. For example, a fluid state causing turbulence is preferred. Also, a spiral vortex may be present therein.

The inlet nozzle for introducing the starting material gas into the reaction tube may be a nozzle for providing a coaxial parallel flow, an oblique flow or a cross flow. However, the present invention is by no means limited thereto. A coaxial parallel flow nozzle is generally preferred in view of the design because of its simple structure, though it is inferior to some extent in the mixing degree to the nozzles capable of providing an oblique flow or a cross flow.

For example, in the case of a coaxial parallel flow nozzle, the titanium tetrachloride-containing gas is introduced through the inner tube. In this case, the inner tube preferably has a diameter of 50 mm or less from the standpoint of mixing the gases.

The gases introduced into the reaction tube flow preferably at a high flow rate within the reaction tube so as to attain complete mixing of gases. The flow rate is preferably 5 m/sec or more in terms of the average flow rate. When the gas flow rate within the reaction tube is 5 m/sec or more, thorough mixing can be attained in the reaction tube. Moreover, the generation of particles grown under CVD-control is reduced and formation of particles having a broad particle size distribution can be prevented.

The reaction occurring within the reaction tube is an exothermic reaction and the reaction temperature is higher than the sintering temperature of fine particles of the produced titanium oxide. Therefore, although the heat is released from the reactor, sintering of the produced fine particles of titanium oxide proceeds, thereby further growing the particles, unless the particles are rapidly cooled after the reaction. In order to produce ultrafine particles of titanium oxide having a specific surface area less than 10 m²/g, the high-temperature (higher than 600° C.) residence time within the reaction tube is preferably controlled to 1.0 second or shorter, followed by quenching. In order to rapidly cool the particles after reaction, a large amount of cooling air or a gas such as nitrogen may be introduced into the reaction mixture, or water may be sprayed thereon.

The titanium oxide produced by the aforementioned method has been subjected to high-temperature thermal hysteresis during synthesis. Since the titanium oxide is in the form of ultrafine particles having high crystallinity, and the obtained primary particles contain no pores or hydroxyl groups. By virtue of a very small particle size, the titanium oxide has a high reactivity, and is capable of readily forming titanium-containing perovskite compound particles only by wet-reaction with an alkaline earth metal compound. The titanium oxide is considered to form titanium-containing perovskite compound particles exhibiting ferroelectricity without heating at higher than 300° C. by virtue of high crystallinity. In contrast, titanium oxide produced by a wet-method is in the form of fine particles, but is short of a high performance (as described in detail later).

The titanium oxide produced as mentioned above hereinafter may be referred to as “vapor-grown titanium oxide.”

In the present invention, the particle size distribution is obtained by employing a laser diffractometry particle diameter measuring method. The procedure of measuring the particle size distribution will be described below.

Pure water (50 mL) and a 10% aqueous sodium hexametaphosphate solution (100 μL) are added to titanium oxide (0.05 g), to thereby form a slurry, which is irradiated with an ultrasonic wave (46 KHz, 65 W) for three minutes. Then, the particle diameter of this slurry is measured by a laser diffractometry particle diameter analyzer (SALD-2000J, product of Shimadzu Corporation). When a mean particle diameter corresponding to a 90% cumulative weight on the particle size distribution curve (D₉₀) is small, good dispersibility in a hydrophilic solvent is considered to be attained.

The thus-produced fine particles of titanium oxide in the present invention have excellent uniformity in the particle size. In the present invention, the uniformity in the particle size is specified by a distribution constant (n) obtained in accordance with the Rosin-Rammler equation. The Rosin-Rammler equation is briefly described below. Details thereof are described in Ceramic Kogaku Handbook (Ceramic Engineering Handbook), compiled by Nippon Ceramics Kyokai, 1st ed., p. 596 to 598.

The Rosin-Rammler equation is represented by the following equation (2):
R=100 exp(−bDⁿ) (2)
wherein D is a particle diameter, R is a percentage of the number of particles larger than D (particle diameter) to the total number of particles, and n is a distribution constant.

Assuming that b=1/Deⁿ, the equation (2) is rewritten as follows:
R=100 exp {−(D/De)ⁿ} (3)
wherein Deⁿ is a particle characteristic constant and n is a distribution constant.

From equation (2) or (3), the following equation (4) is obtained:
log {log(100/R)}=n log D+C (4)
wherein C is a constant. From equation (3), the relationship between log D and log {log(100/R)} is plotted on the Rosin-Rammler (RR) chart where log D is graduated on the x axis and log {log(100/R)} on the y axis. Then, a nearly straight line is obtained. The gradient (n) of this straight line indicates the degree of uniformity of the particle size. It can be said that when the numerical value of n becomes larger, the uniformity of the particle size is higher.

The fine particles of titanium oxide in the present invention preferably have a mean particle diameter corresponding to a 90% cumulative weight on the particle size distribution curve (D₉₀) of 2.2 Mm or less and a distribution constant n of 1.7 or more by the Rosin-Rammler equation.

The fine particles of titanium oxide in the present invention serving as a starting material preferably contain the anatase or brookite crystal mainly as a crystal phase.

The fine particles of titanium oxide in the present invention serving as a starting material may have a necking structure in which primary particles are three-dimensionally linked.

The alkaline earth metal compound employed in the production method in the present invention is preferably water-soluble and is generally a hydroxide, a nitrate, an acetate, a chloride, etc. These compounds may be used singly or in combination of two or more species at arbitrary proportions. From the viewpoint of electric characteristics, a hydroxide is most preferable.

For example, barium titanate as a titanium-containing perovskite compound may be produced by reacting the aforementioned vapor-grown titanium oxide with a barium compound.

The reaction is preferably performed in an alkaline solution containing a basic compound. The pH of the solution is preferably 11 or higher, more preferably 13 or higher, particularly preferably 14 or higher. When the pH is 14 or higher, barium titanate particles having a smaller particle diameter can be produced. It is desirable to maintain the alkaline state of the reaction solution at pH 11 or higher by, for example, addition of an organic basic compound. When the pH is lower than 11, reactivity of vapor-grown titanium oxide with a barium compound diminishes, leading to difficulty in production of barium titanate exhibiting high dielectric constant.

No particular limitation is imposed on the basic compound employed in the present invention, and preferred is a compound gasifying under atmospheric pressure or reduced pressure via vaporization, sublimation and/or pyrolysis. Examples of the basic compound include ammonia, short-chain organic amines having high solubility in water, and organic bases such as hydroxide of ammonium salt.

Of these, hydroxide of ammonium salt is preferred, since they serve as strong bases by virtue of high dissociation degree when dissolved in water, and are non-volatile during reaction.

Examples of known industrial hydroxide of ammonium salt include choline and tetramethylammonium hydroxide (TMAH), which are available at low cost. Particularly, tetramethylammonium hydroxide, which is used in the electronic industry, is preferred, since a product thereof having low impurity content such as metal ions is available, and the hydroxide can be removed as gas through pyrolysis at 135° C. to 140° C.

No particular limitation is imposed on the type of the basic compounds. These basic compounds may be used singly or in combination of two or more species at arbitrary proportions.

Through control of the carbonate moiety (including carbonate species: CO₂, H₂CO₃, HCO₃⁻, and CO₃²⁻) concentration of the reaction solution, barium titanate having a high dielectric constant can be stably produced.

The reaction solution preferably has a carbonate moiety concentration (unless otherwise specified, as reduced to CO₂) of 500 mass ppm or less, more preferably 1 to 200 mass ppm, particularly preferably 1 to 100 mass ppm. When the carbonate moiety concentration falls outside the above ranges, barium titanate exhibiting ferroelectricity may fail to be produced.

Preferably, the reaction solution has a particulate titanium oxide particles at a concentration of 0.1 to 5 mol/L and a barium compound at a concentration of 0.1 to 5 mol/L.

In the most typical industrial procedure, the reaction is performed with heating and stirring. Upon reaction, the thus-prepared alkaline solution is generally maintained at 40° C. to the boiling temperature of the solution, preferably at 80° C. to the boiling temperature of the solution, through heating with stirring under atmospheric pressure. The reaction time is generally one hour or longer, preferably four hours or longer. Although specifically designed apparatus is required, the reaction is preferably performed under high-temperature/pressure conditions (100° C. to critical point of the solution) so as to raise the reaction temperature, leading to enhancement of crystallinity of barium titanate.

The method of the invention may further include a step of removing a basic compound and impurity ions in the obtained slurry after completion of reaction by using electrodialysis, ion exchange, washing with water, washing with solvent, treatment with osmotic film, etc.

After completion of reaction, the obtained slurry is subjected to solid-liquid separation and drying, whereby barium titanate particles in the present invention can be produced. Examples of the solid-liquid separation step include sedimentation, concentration and filtration. During the steps of sedimentation, concentration and filtration, a flocculent or a dispersant may be employed so as to modify sedimentation speed or filtration speed.

The drying by evaporating a liquid component may be carried out by, for example, drying under reduced pressure, drying under hot blow or freeze-drying. In the present invention, preferably, a basic compound such as tetramethylammonium hydroxide or choline is gasified through vaporization, sublimation and/or pyrolysis under reduced pressure or atmospheric pressure for removal. The removal is generally performed at room temperature to 300° C. No particular limitation is imposed on the atmosphere under which drying is performed, and drying is generally performed in air. After drying, a step of pulverization or crushing to produce barium titanate powder may further be provided.

The barium titanate powder may further be calcined in order to enhance crystallinity of barium titanate particles. The calcining is generally performed under atmospheric pressure or reduced pressure at 300 to 1,200° C. No particular limitation is imposed on the atmosphere under which calcining is performed, and calcining is generally performed in air. After completion of calcining and pulverization or mixing, repeating the calcining step is preferable, since crystallinity of the product is enhanced.

The titanium-containing perovskite compound synthesized by a conventional wet method employing titanium oxide sol exhibits paraelectricity. On the other hand, the titanium-containing perovskite compound in the present invention having a primary particle diameter of 15 to 200 nm exhibits ferroelectricity.

Although the reason is not known exactly, one possible reason is that the titanium-containing perovskite compound in the present invention has a crystallinity higher than that of the titanium-containing perovskite compound synthesized by a conventional wet method employing titanium oxide sol. More specifically, when the particle diameter is less than 15 nm, crystal growth is difficult due to such a small particle diameter, whereas when the particle diameter is greater than 200 nm, reactivity and crystallinity are diminished. In other words, the titanium-containing perovskite compound in the present invention has excellent electric characteristics, exhibiting ferroelectricity when having a particle diameter of 15 to 200 nm.

Examples of titanium oxide particles contained in titanium oxide sol include those generally having a primary particle diameter of 5 to 50 nm, and examples of vapor-grown titanium oxide particles include those generally having a primary particle diameter of 7 to 500 nm. As compared with titanium oxide sol, vapor-grown titanium oxide particles are difficult to aggregate in a reaction system containing an alkaline earth metal compound. Therefore, the primary particle diameter of the titanium-containing perovskite compound particles can be maintained 50 to 200% the primary particle diameter of vapor-grown titanium oxide particles, which is maintained almost the same as the primary particle diameter. One conceivable reason why vapor-grown titanium oxide is difficult to aggregate in a reaction system containing an alkaline earth metal compound is the presence of three-dimensional necking structure.

A titanium-containing perovskite compound as one of the embodiments of the present invention exhibits excellent dispersibility and heat resistance, as compared with a titanium-containing perovskite compound synthesized by a conventional wet method employing titanium oxide sol. Although the reason is not known exactly, one possible reason is that the titanium-containing perovskite compound according to the present invention is difficult to aggregate and has surface conditions different from those of titanium-containing perovskite compound particles synthesized by a conventional wet method employing titanium oxide sol.

With respect to the method according to the present invention for producing a titanium-containing perovskite compound, a production equipment can be simplified as compared with a conventional method for producing a titanium-containing perovskite compound employing titanium oxide sol. The titanium-containing perovskite compound synthesized by a conventional wet method employing titanium oxide sol requires a step of calcining at 300 to 1,200° C., whereas the titanium-containing perovskite compound in the present invention does not require the calcining step. In the case where titanium oxide sol is used, the titanium oxide sol is gradually added by small portion through a method such as dropwise addition, in order to prevent aggregation of titanium oxide particles in a reaction solution and produce a titanium-containing perovskite compound exhibiting excellent dispersibility. In contrast, since vapor-grown titanium oxide particles are considerably difficult to aggregate in a reaction solution as compared with titanium oxide sol, vapor-grown titanium oxide and an alkaline earth metal compound can be added simultaneously to a reaction solution.

Titanium oxide sol lowers alkalinity of a reaction solution due to water contained in the sol. In contrast, vapor-grown titanium oxide does not lower alkalinity of a reaction solution. Therefore, when an equal amount of a basic compound is added, a titanium-containing perovskite compound having higher crystallinity can be produced from vapor-grown titanium oxide.

(III) Use of Titanium-Containing Perovskite Compound

The thus-produced titanium-containing perovskite compound is molded into dielectric ceramics, pyroelectric ceramics, a piezoelectric ceramics and a thin-film product.

These ceramic products and thin-film product are employed, for example, as a capacitor material and in a sensor.

No particular limitation is imposed on the articles employing the ceramic product or thin-film product. Examples of the articles include power generators; vehicles such as automobiles and trains; machine tools; household electric appliances such as television sets, personal computers and refrigerators; and electronic devices such as large-scale computers and mobile phones.

The titanium-containing perovskite compound in the present invention may be processed into a slurry or a paste by use of water or a solvent. The slurry or paste may be mixed with materials such as a filler, an additive, a binder or a similar material other than the titanium-containing perovskite compound.

The titanium-containing perovskite compound fine particles in the present invention may be molded into a disk with additives such as a sintering aid. Alternatively, a slurry or paste containing the particles may be molded into a thin film with additives. These molded products may be calcined under appropriate conditions, thereby providing products.

In order to enhance performance of electronic devices, a ceramic capacitor is required to exhibit excellent temperature characteristics and a life property. In this connection, there has been proposed a dielectric ceramic composition containing ceramic particles of a core-shell structure to serve as a material for producing a dielectric layer employed in the ceramic capacitor. In order to control reactivity of a titanium-containing perovskite compound with a rare earth metal element, the titanium-containing perovskite compound is required to have high heat resistance. The titanium-containing perovskite compound according to the present invention, having excellent heat resistance, is suitable for providing a dielectric ceramic composition containing ceramic particles of a core-shell structure. Through calcining, the titanium-containing perovskite compound in the present invention exhibits a high content of tetragonal crystals. Thus, a titanium-containing perovskite compound according to the present invention is suitable for a dielectric material for producing a laminate ceramic capacitor.

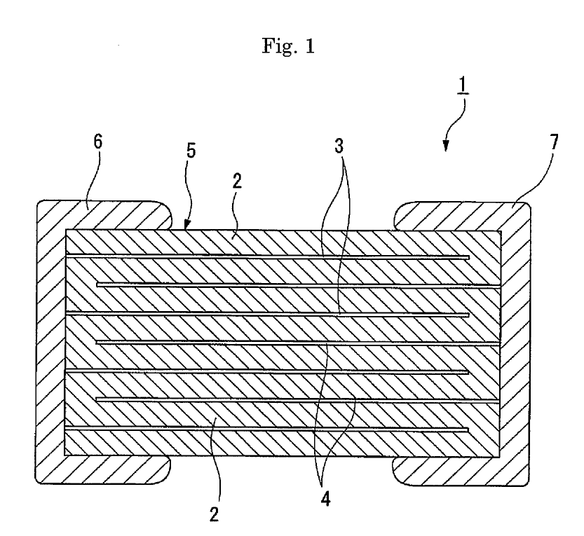

FIG. 1 shows a schematic cross sectional view of a laminated ceramic capacitor as an example of capacitors.

The laminated ceramic capacitor (1) comprises a laminated body comprising a dielectric material layer (2) and internal electrodes (3, 4) laminated sequentially on each other and external electrodes (6, 7) provided on the side of the laminated body (5). The side ends of the each internal electrode (3, 4) are exposed on the side of the laminated body (5), and one of the other two ends is respectively connected to one of the external electrodes (6, 7).

The dielectric material layer (2) is formed by solidifying and shaping powder of a titanium-containing perovskite composite oxide using a binder or the like. The internal electrodes (3, 4) are composed of Ni, Pd, Ag, etc. The external electrodes (6, 7) are composed of a sintered body of Ag, Cu, Ni, etc. on which Ni is plated.

The capacitor (1) shown in FIG. 1 is used, for example, by being mounted on a circuit substrate (11) of a mobile phone (10).

Next, an example of producing methods of the above-mentioned laminated ceramic capacitor is described.

First, a slurry is produced by mixing powder of a titanium-containing perovskite composite oxide with a binder, a dispersion agent and water. The slurry is preferably vacuum deaerated in advance.

Next, after thinly applying the slurry on a substrate by a doctor blade method and the like, water is evaporated by heating to thereby form a dielectric material layer mainly comprising powder of a titanium-containing perovskite composite oxide.

Next, a metal paste such as Ni, Pd and Ag is applied on the obtained dielectric material layer, another dielectric material layer is laminated thereon, and further a metal paste serving as an internal electrode is applied. By repeating the step, a laminated body is obtained wherein dielectric layers and internal electrodes are laminated sequentially. The laminated body is preferably pressed for firm adhesion between the dielectric layers and internal electrodes.

Next, after being cut in a size of a capacitor, the laminated body is calcined at a temperature from 1,000° C. to 1350° C. An external electrode paste is applied on the side of the laminated body after calcining, and then calcined a temperature from 600° C. to 850° C. Lastly, Ni is plated on the surface of the external electrode.

A laminated ceramic capacitor (1) shown in FIG. 1 is obtained as mentioned above.

By using a titanium-containing perovskite composite oxide, which is one of the preferable embodiments of the present invention, as a dielectric material, electrostatic capacity of the laminated ceramic capacitor (1) can be increased. By using a titanium-containing perovskite composite oxide, which is one of the preferable embodiments of the present invention, as a dielectric material, the thickness of the dielectric material layer of the laminated ceramic capacitor (1) can be reduced, which enables to make the size of the capacitor smaller. The electrostatic capacity of the capacitor can be further increased by reducing the thickness of the dielectric material layer.

Such a small-size laminated ceramic capacitor can be suitably used as parts for electronic devices, specifically portable devices such as mobile phones.

By dispersing a filler containing the titanium-containing a perovskite compound in the present invention in at least one member selected from thermosetting resin and thermoplastic resin, a film exhibiting a high dielectric constant can be produced. In the case in which a filler other than the titanium-containing perovskite compound is added to the resin, the filler may be at least one member selected from the group containing alumina, titania, zirconia, tantalum oxide, strontium titanate, calcium titanate, etc. No particular limitation is imposed on the thermosetting resin and thermoplastic resin to be employed. Examples of the thermosetting resin include epoxy resin, polyimide resin and bistriazine resin, and examples of the thermoplastic resin include polyolefin resin, styrene resin and polyamide.

In order to uniformly dispersing a filler containing the titanium-containing perovskite compound in the present invention in at least one member selected from thermosetting resin and thermoplastic resin, the filler is preferably dispersed in advance in a solvent or a mixture of the aforementioned resin composition and a solvent, thereby forming a slurry.

When the slurry is formed by dispersing a filler in a solvent or a mixture of the aforementioned resin composition and a solvent, wet crushing is preferably employed.

No particular limitation is imposed on the solvent, and examples include methyl ethyl ketone, toluene, ethyl acetate, methanol, ethanol, N,N-dimethylformamide, N,N-dimethylacetamide, N-methylpyrrolidone and methyl cellosolve. These solvents may be used singly or in combination of two or more species.

When the slurry is formed by dispersing a filler in a solvent or a mixture of the aforementioned resin composition and a solvent, a coupling agent is preferably incorporated. No particular limitation is imposed on the type of coupling agent, and silane coupling agents, titanate coupling agents, aluminate coupling agents, etc. may be used. When a hydrophilic group of a coupling agent is reacted with active hydrogen present on the surface of the filler containing a titanium-containing perovskite compound, the filler is covered with the coupling agent. The thus-coated filler exhibits excellent dispersibility in a solvent. Through appropriate choice of the hydrophobic group of the coupling agent, compatibility of the coated filler with resin can be enhanced. When epoxy resin is employed as the resin, preferably used is a silane coupling agent having any of monoamino, diamino, cationic styryl, epoxy, mercapto, anilino, ureido and the like, serving as a functional group; or a titanate coupling agent having any of phosphito, amino, diamino, epoxy, mercapto and the like, serving as a functional group. When polyimide resin is employed as the resin, preferably used is a silane coupling agent having any of monoamino, diamino, anilino and the like, serving as a functional group; or a titanate coupling agent having any of monoamino, diamino and the like, serving as a functional group. These coupling agents may be used singly or in combination of two or more species.

When the amount of the coupling agent is less than the amount so as to sufficiently cover the surface of the filler containing a titanium-containing perovskite compound, the coupling agent cannot be very effective, whereas when the amount is excessively large, the excess portion remains unreacted, thereby adversely affecting the resin composition. Thus, a coupling agent is preferably incorporated into resin in an amount of 0.05 to 20 mass % of the filler containing a titanium-containing perovskite compound, although the amount may vary depending on the particle diameter of particles of the filler containing a titanium-containing perovskite compound or the type of the coupling agent. In order to complete reaction between the hydrophilic group of the coupling agent and active hydrogen present on the surface of the filler containing a titanium-containing perovskite compound, after forming a slurry thereof, it is preferable to provide a step of heating the slurry. Although no particular limitation is imposed on the temperature and time of heating, the heating is preferably performed at 100 to 150° C. for one hour to three hours. When the boiling point of the solvent is 100° C. or lower, preferably, the heating temperature is controlled to be not higher than the boiling point, and the reaction temperature is prolonged in accordance with the heating temperature.

When an electronic part is produced from a filler containing a titanium-containing perovskite compound according to the present invention, high-performance electronic parts exhibiting further enhanced electric characteristics can be produced by increasing the filler content (percent amount of the filler containing a titanium-containing perovskite compound in the present invention). For example, multi-component particles containing a titanium-containing perovskite compound according to the present invention is prepared by formulating particles on the basis of the fuller index such that the minimum porosity is generated. As used herein, the term “multi-component particles” refers to particles which may be prepared from at least one member selected from the group consisting of primary particles of the titanium-containing perovskite compound in the present invention having different particle diameters, a calcined product of particles of the titanium-containing perovskite compound in the present invention having different particle diameters, alumina, titania, zirconia, tantalum oxide, strontium titanate, calcium titanate, etc.

### BEST MODE FOR CARRYING OUT THE INVENTION

The present invention will next be described in detail by way of Examples and Comparative Examples, which should not be construed as limiting the invention thereto.

<Method for Determining Ferroelectricity>

Ferroelectricity is evaluated by either of the following procedures, and it does not necessarily satisfy the both standards. In the case of using a differential scanning calorimeter, a sample is dried at 300° C. or higher for one hour or longer. The dried sample (about 20 mg) is weighed by use of a sample container of a differential scanning calorimeter, and heated from −30° to 200° C. at a constant rate of 1 to 20° C./min. If the sample exhibits ferroelectricity, an endothermic peak attributed to the heat required for transition to the cubic crystals appears during the course of temperature elevation. Whether or not the sample exhibits ferroelectricity is determined on the basis of the presence of the peak.

Ferroelectricity may also be evaluated by XRD measurement of the ratio of the tetragonal barium titanate. A cubic crystal may be discerned from a tetragonal crystal as follows: a half peak width at each of the two peaks observed at the location of the single line (111) plane and the double line (200, 002) plane (in the vicinity of 2θ=39° and 46° respectively) of a tetragonal crystal is compared to determine the ratio of the half peak width of the double line to that of the single line. The ratio becomes 1 in a cubic crystal. When the half peak width of the double line becomes larger than that of the single line, ferroelectricity of the barium titanate becomes higher. Ferroelectricity of the barium titanate becomes maximum when the ratio of the half peak width of the double line to that of the single line is 2.

In the case of using a differential scanning calorimeter, it is difficult to detect an endothermic peak if the sensitivity of the calorimeter is low. In such a case, evaluation by XRD method is preferable.

### EXAMPLE 1

A titanium tetrachloride-containing gas prepared by mixing gaseous titanium tetrachloride (4.7 Nm³/hr) (N denotes normal states, hereinafter the same applies) and nitrogen (16 Nm³/hr) was preliminary heated to 1,100° C. An oxidizing gas containing air (20 Nm³/hr) and steam (25 Nm³/hr) was preliminary heated to 1,000° C. The two gases were introduced into a reaction tube through a coaxial parallel flow nozzle at flow rates of 92 m/sec and 97 m/sec, respectively. The coaxial parallel flow nozzle had an inner tube diameter of 20 mm, and the titanium tetrachloride-containing gas was introduced through the inner tube.

The reaction tube had an inside diameter of 100 mm and the flow rate within the reaction tube at a reaction temperature of 1,250° C. was found to be 13 m/sec (calculated). After completion of reaction, a cooling air was introduced into the reaction tube so that the high-temperature residence time in the reaction tube could be 0.2 seconds. Subsequently, the ultrafine particle powder was collected by use of a Teflon®-made bag filter.

The thus-obtained fine particles of titanium oxide were found to have a BET specific surface area of 102 m²/g, and contain anatase crystals (92%) and rutile crystals (8%). Through measurement of particle size distribution by means of a laser diffractometry particle size distribution measuring method, the obtained fine particles of titanium oxide were found to have a mean particle diameter corresponding to a 90% cumulative weight on the particle size distribution curve (D₉₀) of 2.0 μm. The n value as calculated from the Rosin-Rammler equation was 1.9. The n value was obtained by plotting three-point data D₁₀, D₅₀ and D₉₀ obtained in the laser diffraction on the RR chart as R=90%, 50% and 10%, respectively, and determined from an approximate straight line drawn on these three points.

The specific surface area of the thus-produced vapor-grown titanium oxide was determined through the BET method. The primary particle diameter as calculated from equation (1) was 15 nm.

Under nitrogen flow, a 20 mass % aqueous tetramethylammonium hydroxide solution (carbonate concentration: 60 ppm or less, product of Sacheem Showa) (456 g), barium hydroxide octahydrate (product of Nippon Solvay K. K.) (126 g), and the aforementioned vapor-grown titanium oxide (32 g) were fed to a reactor equipped with a reflux condenser. The resultant aqueous solution adjusted to pH 14 was boiled with stirring. Boiling state was maintained for four hours for reaction. Subsequently, the reaction mixture was allowed to cool down to 50° C., followed by filtration.

The residue of filtration was dried at 300° C. for five hours, to thereby yield a particulate powder. The yield (actual yield/theoretical yield) was 99% as calculated from the amounts of titanium oxide and barium hydroxide used in the reaction.

The thus-dried powder was crushed by use of a mortar. The crushed powder was analyzed in terms of X-ray diffraction peak by means of an X-ray diffractometer (RAD-B Roter Flex, product of Rigaku Corporation). As a result, the obtained powder was identified as perovskite-type BaTiO₃.

The specific surface area of the thus-produced particles was determined through the BET method. The primary particle diameter as calculated from equation (1) was 25 nm, which is almost equivalent to the primary particle diameter of the titanium oxide.

The powder was analyzed in terms of ferroelectricity by use of a differential scanning calorimeter. An endothermic peak having a peak area of 8 mJ/mg was observed at about 130° C. The result indicated that the particles exhibited ferroelectricity.

The ratio of the half peak width of the double line to that of the single line measured by XRD was 1.2. The result indicated that the particles exhibited ferroelectricity.

The thus-produced particles (900 mg) were kneaded with a binder (0.1 mL) containing 30 mass % poly(vinyl alcohol), and the kneaded product was press-molded to thereby form pellets (diameter: 10 mm, apparent specific gravity: 3.2). The shrinking percentage of the pellets in the thickness direction caused by heating from room temperature to 1,100° C. was determined by use of a thermo-mechanical analyzer (TMA 8310, product of Rigaku Corporation) at a temperature elevation rate of 20° C./min. The shrinking percentage was determined to be 10%.

The thus-produced fine particles (5 g) were placed on a ceramic plate and subjected to heating to 950° C. at 20° C./min in an electric furnace, maintaining at 950° C. for two hours (calcining), and natural cooling. The specific surface area of the thus-produced powder was determined through the BET method. The primary particle diameter as calculated from equation (1) was 26 nm. The c/a ratio was calculated to be 1.0091, through Rietveld analysis of X-ray diffraction intensity data.

The dried fine particles (17 g) were subjected to wet crushing for 30 minutes by use of a paint-shaker in which methyl ethyl ketone (40 g) and zirconia balls (3 mmφ) were placed. The particle size distribution of the crushed product was determined by use of a centrifugal sedimentation-type particle size distribution analyzer (SA-CP4L, Shimadzu Corporation).

From the determined particle size distribution, mean diameters at a 10% cumulative weight (D₁₀), a 50% cumulative weight (D₅₀) and a 90% cumulative weight (D₉₀) were determined to be 0.03 μm, 0.09 μm and 0.50 μm, respectively.

Dielectric ceramics, a dielectric film, a thin-film product such as a dielectric coating film, a capacitor and a piezoelectric material produced by using the titanium-containing perovskite compound obtained above exhibited excellent characteristics.

### EXAMPLE 2

A titanium tetrachloride-containing gas prepared by mixing gaseous titanium tetrachloride (9.4 Nm³/hr) and nitrogen (6 Nm³/hr) was preliminary heated to 1,000° C. An oxidizing gas containing oxygen (10 Nm³/hr) and steam (30 Nm³/hr) was preliminary heated to 1,000° C. The two gases were introduced into a reaction tube through a coaxial parallel flow nozzle at flow rates of 63 m/sec and 73 m/sec, respectively. The coaxial parallel flow nozzle had an inner tube diameter of 20 mm, and the titanium tetrachloride-containing gas was introduced through the inner tube.

The reaction tube had an inside diameter of 100 mm and the flow rate within the reaction tube at a reaction temperature of 1,310° C. was found to be 13 m/sec (calculated). After completion of reaction, a cooling air was introduced into the reaction tube so that the high-temperature residence time in the reaction tube could be 0.2 seconds. Subsequently, the fine particle powder was collected by use of a Teflon®-made bag filter.

The thus-obtained fine particles of titanium oxide were found to have a BET specific surface area of 26 m²/g and a primary particle diameter of 60 nm, and contain anatase crystals (80%) and rutile crystals (20%). Through measurement of particle size distribution by means of a laser diffractometry particle size distribution measuring method, the obtained fine particles of titanium oxide were found to have a mean particle diameter corresponding to a 90% cumulative weight on the particle size distribution curve (D₉₀) of 0.8 μm. The n value as calculated from the Rosin-Rammler equation was 2.6.

Barium titanate was synthesized by the same procedure as in Example 1, except that the above titanium oxide having a primary particle diameter of 60 nm was used as vapor-grown titanium oxide.

The yield (actual yield/theoretical yield) was 99%.

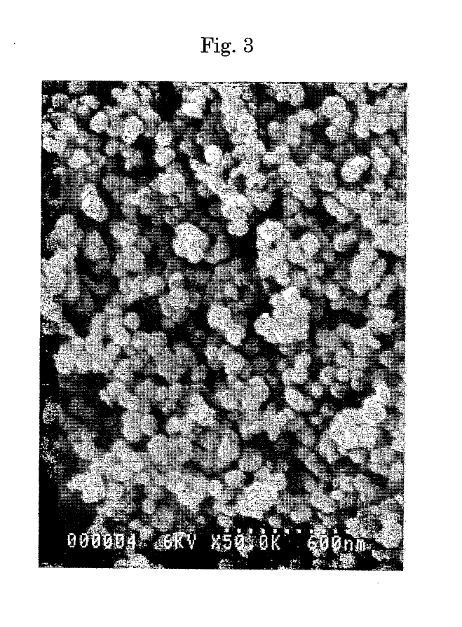

The obtained powder was identified as perovskite-type BaTiO₃ having a primary particle diameter of 61 nm. FIG. 3 shows an SEM photograph of the particles.

The powder was analyzed in terms of ferroelectricity by use of a differential scanning calorimeter. An endothermic peak having a peak area of 47 mJ/mg was observed at about 130° C., which indicated that the particles exhibited ferroelectricity.

The ratio of the half peak width of the double line to that of the single line measured by XRD was 1.4. The result indicated that the particles exhibited ferroelectricity.

In a manner similar to that of Example 1, pellets (apparent specific gravity: 3.2) were produced. The shrinking percentage caused by heating from room temperature to 1,100° C. was determined to be 1%.

In a manner similar to that of Example 1, the fine particles were subjected to heating to 1,020° C. and maintaining at 1,020° C. for two hours. The primary particle diameter of the calcined powder was 0.28 μm. The c/a ratio was calculated to be 1.0089.

In a manner similar to that of Example 1, the fine particles were subjected to wet crushing by use of a paint-shaker, and the crushed product was found to have D₁₀, D₅₀ and D₉₀ of 0.06 μm, 0.24 μm and 0.52 μm, respectively.

Dielectric ceramics, a dielectric film, a thin-film product such as a dielectric coating film, a capacitor and a piezoelectric material produced by using the barium titanate obtained above exhibited excellent characteristics.

### EXAMPLE 3

A gas containing gaseous titanium tetrachloride (concentration: 100%) (11.8 Nm³/hr) was preliminary heated to 1,000° C. A mixed gas containing oxygen (8 Nm³/hr) and steam (20 Nm³/hr) was preliminary heated to 1,000° C. The two gases were introduced into a reaction tube through a coaxial parallel flow nozzle at flow rates of 49 m/sec and 60 m/sec, respectively. The coaxial parallel flow nozzle had an inner tube diameter of 20 mm, and the titanium tetrachloride-containing gas was introduced through the inner tube.

The reaction tube had an inside diameter of 100 mm and the flow rate within the reaction tube at a reaction temperature of 1,320° C. was found to be 10 m/sec (calculated). After completion of reaction, a cooling air was introduced into the reaction tube so that the high-temperature residence time in the reaction tube could be 0.3 seconds or shorter. Subsequently, the produced fine particle powder was collected by use of a Teflon®-made bag filter.

The thus-obtained fine particles of titanium oxide were found to have a BET specific surface area of 16 m²/g and a primary particle diameter of 90 nm, and contain anatase-form crystals (80%) and rutile-form crystals (20%). Through measurement of particle size distribution by means of a laser diffractometry particle size distribution measuring method, the obtained fine particles of titanium oxide were found to have a mean particle diameter corresponding to a 90% cumulative weight on the particle size distribution curve (D₉₀) of 0.8 μm. The n value as calculated from the Rosin-Rammler equation was 2.8.

Barium titanate was synthesized by the same procedure as in Example 1, except that the above titanium oxide having a primary particle diameter of 90 nm was used as vapor-grown titanium oxide.

The yield (actual yield/theoretical yield) was 99%.

The obtained powder was identified as perovskite-type BaTiO₃ having a primary particle diameter of 75 nm.

The powder was analyzed in terms of ferroelectricity by use of a differential scanning calorimeter. An endothermic peak having a peak area of 69 mJ/mg was observed at about 130° C., which indicated that the particles exhibited ferroelectricity.

The ratio of the half peak width of the double line to that of the single line measured by XRD was 1.9. The result indicated that the particles exhibited ferroelectricity.

In a manner similar to that of Example 1, pellets (apparent specific gravity: 3.3) were produced. The shrinking percentage caused by heating from room temperature to 1,100° C. was determined to be 0.5%.

In a manner similar to that of Example 1, the fine particles were subjected to heating to 1,100° C. and maintaining at 1,100° C. for two hours. The primary particle diameter of the calcined powder was 0.25 μm. The c/a ratio was calculated to be 1.0089.

In a manner similar to that of Example 1, the fine particles were subjected to wet crushing by use of a paint-shaker, and the crushed product was found to have D₁₀, D₅₀, and D₉₀ of 0.08 μm, 0.33 μm and 0.54 μm, respectively.

Dielectric ceramics, dielectric film, a thin-film product such as dielectric coating film, a capacitor and a piezoelectric material produced by using the barium titanate obtained above exhibited excellent characteristics.

### EXAMPLE 4

A gas containing gaseous titanium tetrachloride (concentration: 100%) (11.8 Nm³/hr) was preliminary heated to 900° C. A mixed gas containing oxygen (5 Nm³/hr) and steam (25 Nm³/hr) was preliminary heated to 900° C. The two gases were introduced into a reaction tube through a coaxial parallel flow nozzle at flow rates of 45 m/sec and 52 m/sec, respectively. The coaxial parallel flow nozzle had an inner tube diameter of 20 mm, and the titanium tetrachloride-containing gas was introduced through the inner tube.

The reaction tube had an inside diameter of 100 mm and the flow rate within the reaction tube at a reaction temperature of 1,050° C. was found to be 9 m/sec (calculated) After completion of reaction, a cooling air was introduced into the reaction tube so that the high-temperature residence time in the reaction tube could be 2.5 seconds. Subsequently, the fine particle powder was collected by use of a Teflon®-made bag filter.

The thus-obtained fine particles of titanium oxide were found to have a BET specific surface area of 10 m²/g and a primary particle diameter of 150 nm, and contain anatase crystals (90%) and rutile crystals (10%). Through measurement of particle size distribution by means of a laser diffractometry particle size distribution measuring method, the obtained fine particles of titanium oxide were found to have a mean particle diameter corresponding to a 90% cumulative weight on the particle size distribution curve (D₉₀) of 0.9 μm. The n value as calculated from the Rosin-Rammler equation was 2.6.

Barium titanate was synthesized by the same procedure as in Example 1, except that the above titanium oxide having a primary particle diameter of 150 nm was used as vapor-grown titanium oxide.

The yield (actual yield/theoretical yield) was 99%.

The obtained powder was identified as perovskite-type BaTiO₃ having a primary particle diameter of 170 nm.

The powder was analyzed in terms of ferroelectricity by use of a differential scanning calorimeter. An endothermic peak having a peak area of 144 mJ/mg was observed at about 130° C. The result indicated that the particles exhibited ferroelectricity.

The ratio of the half peak width of the double line to that of the single line measured by XRD was 2.0. The result indicated that the particles exhibited ferroelectricity.

In a manner similar to that of Example 1, pellets (apparent specific gravity: 3.2) were produced. The shrinking percentage caused by heating from room temperature to 1,100° C. was determined to be 0.2%.

In a manner similar to that of Example 1, the fine particles were subjected to heating to 1,200° C. and maintaining at 1,200° C. for two hours. The primary particle diameter of the calcined powder was 0.23 μm. The c/a ratio was calculated to be 1.0087.

In a manner similar to that of Example 1, the fine particles were subjected to wet crushing by use of a paint-shaker, and the crushed product was found to have D₁₀, D₅₀ and D₉₀ of 0.17 μm, 0.40 μm and 0.58 μm, respectively.

Dielectric ceramics, a dielectric film, a thin-film product such as a dielectric coating film, a capacitor and a piezoelectric material produced by using the barium titanate obtained above exhibited excellent characteristics.

### EXAMPLE 5

Barium titanate was synthesized by the same procedure as in Example 1, except that the above titanium oxide having a primary particle diameter of 60 nm was used as vapor-grown titanium oxide and that barium hydroxide octahydrate (119.9 g) and calcium hydroxide (1.5 g) were used instead of barium hydroxide octahydrate (120 g).

The yield (actual yield/theoretical yield) was 99%.

The obtained powder was identified as perovskite-type Ba_{0.95}Ca_{0.05}TiO₃ having a primary particle diameter of 60 nm.

The powder was analyzed in terms of ferroelectricity by use of a differential scanning calorimeter. An endothermic peak having a peak area of 50 mJ/mg was observed at about 130° C., which indicated that the particles exhibited ferroelectricity.

The ratio of the half peak width of the double line to that of the single line measured by XRD was 1.4. The result indicated that the particles exhibited ferroelectricity.

In a manner similar to that of Example 1, pellets (apparent specific gravity: 3.2) were produced. The shrinking percentage caused by heating from room temperature to 1,100° C. was determined to be 1%.

In a manner similar to that of Example 1, the fine particles were subjected to heating to 1,050° C. and maintaining at 1,050° C. for two hours. The primary particle diameter of the calcined powder was 0.21 μm. The c/a ratio was calculated to be 1.0099.

In a manner similar to that of Example 1, the fine particles were subjected to wet crushing by use of a paint-shaker, and the crushed product was found to have D₁₀, D₅₀, and D₉₀ of 0.07 μm, 0.21 μm, and 0.54 μm, respectively.

Dielectric ceramics, dielectric film, a thin-film product such as dielectric coating film, a capacitor and a piezoelectric material produced by using the barium titanate obtained above exhibited excellent characteristics.

### COMPARATIVE EXAMPLE 1

Water was added to titanium tetrachloride (purity: 99.9%), to thereby prepare a 0.25 mol/L (titanium oxide 2 mass %) titanium tetrachloride solution. During preparation, the solution was cooled by an appropriate cooling means such as ice-cooling so that the solution temperature did not rise to 50° C. or higher. The thus-prepared aqueous solution (1 L) was fed to a reaction tank equipped with a reflux condenser and heated to a temperature almost equivalent to the boiling temperature (104° C.). The solution was maintained at the temperature for 60 minutes in order to hydrolyze. The formed sol was cooled, and chlorine formed during reaction and remaining in the solution were removed through electrodialysis. The thus-produced titanium oxide fine particles have a BET specific surface area of 120 m²/g and a primary particle diameter of 12 nm, and contain brookite crystals (80%) and anatase crystals (20%).

Barium titanate was synthesized by the same procedure as in Example 1, except that the above titanium oxide was used as titanium oxide.

The yield (actual yield/theoretical yield) was 99%.

The obtained powder was identified as perovskite-type BaTiO₃ having a primary particle diameter of 24 nm.

The powder was analyzed in terms of ferroelectricity by use of a differential scanning calorimeter. No endothermic peak attributed to phase transition was observed, indicating that the particles exhibited no ferroelectricity.

The ratio of the half peak width of the double line to that of the single line measured by XRD was 1.0.

In a manner similar to that of Example 1, pellets (apparent specific gravity: 3.2) were produced. The shrinking percentage caused by heating from room temperature to 1,100° C. was determined to be 18%.

In a manner similar to that of Example 1, the fine particles were subjected to heating to 900° C. and maintaining at 900° C. for two hours. The primary particle diameter of the calcined powder was 0.16 μm. The c/a ratio was calculated to be 1.0088.

In a manner similar to that of Example 1, the fine particles were subjected to wet crushing by use of a paint-shaker, and the crushed product was found to have D₁₀, D₅₀ and D₉₀ of 0.40 μm, 1.60 μm and 3.3 μm, respectively.

Barium titanate obtained from titanium oxide sol serving as a starting material exhibited no ferroelectricity, and inferior heat resistance and dispersibility.

### COMPARATIVE EXAMPLE 2

A titanium tetrachloride-containing gas prepared by mixing gaseous titanium tetrachloride (10 Nm³/hr) and nitrogen (8 Nm³/hr) was preliminary heated to 1,100° C. An oxidizing gas containing oxygen (5 Nm³/hr) and steam (24 Nm³/hr) was preliminary heated to 1, 100° C. The two gases were introduced into a reaction tube through a coaxial parallel flow nozzle at flow rates of 80 m/sec and 56 m/sec, respectively. The coaxial parallel flow nozzle had an inner tube diameter of 20 mm, and the titanium tetrachloride-containing gas was introduced through the inner tube.

The reaction tube had an inside diameter of 100 mm and the flow rate within the reaction tube at a reaction temperature of 1,280° C. was found to be 12 m/sec (calculated). After completion of reaction, a cooling air was introduced into the reaction tube so that the high-temperature residence time in the reaction tube could be 1.5 seconds. Subsequently, the fine particle powder was collected by use of a Teflon®-made bag filter.

The thus-obtained fine particles of titanium oxide were found to have a BET specific surface area of 16 m²/g and a primary particle diameter of 90 nm, and contain anatase crystals (10%) and rutile crystals (90%). Through measurement of particle size distribution by means of a laser diffractometry particle size distribution measuring method, the obtained fine particles of titanium oxide were found to have a mean particle diameter corresponding to a 90% cumulative weight on the particle size distribution curve (D₉₀) of 0.8 μm. The n value as calculated from the Rosin-Rammler equation was 2.8.

Barium titanate was synthesized by the same procedure as in Example 1, except that the above titanium oxide was used as vapor-grown titanium oxide.

The yield (actual yield/theoretical yield) was 99%.

The obtained powder was identified as perovskite-type BaTiO₃ having a primary particle diameter of 80 nm.

The powder was analyzed in terms of ferroelectricity by use of a differential scanning calorimeter. No endothermic peak attributed to phase transition was observed, indicating that the particles exhibited no ferroelectricity.

The ratio of the half peak width of the double line to that of the single line measured by XRD was 1.0.

In a manner similar to that of Example 1, pellets (apparent specific gravity: 3.3) were produced. The shrinking percentage caused by heating from room temperature to 1,100° C. was determined to be 0.5%.

In a manner similar to that of Example 1, the fine particles were subjected to heating to 1,100° C. and maintaining at 1,100° C. for two hours. The primary particle diameter of the calcined powder was 0.23 μm. The c/a ratio was calculated to be 1.0065.

In a manner similar to that of Example 1, the fine particles were subjected to wet crushing by use of a paint-shaker, and the crushed product was found to have D₁₀, D₅₀ and D₉₀ of 0.09 μm, 0.35 μm and 0.55 μm, respectively.

Vapor-grown titanium oxide having a rutile crystal content of 90% exhibited poor reactivity, and barium titanate obtained therefrom exhibited no ferroelectricity.

### INDUSTRIAL APPLICABILITY

The titanium-containing perovskite compound according to the present invention is produced by a wet-synthesis method, and the particles of the compound have a primary particle diameter almost equivalent to that of titanium oxide particles. The compound of the invention exhibits ferroelectricity. The particles of the compound have a small particle diameter, and exhibit excellent dispersibility, high heat resistance and excellent electric characteristics.

Using a dielectric material such as dielectric ceramics which are produced from a titanium-containing perovskite compound as one of the embodiments of the present invention enables to produce small-size electronic parts such as a laminated ceramic capacitor, a capacitor built in a substrate, a film capacitor and a piezoelectric material. By use of the electronic parts in an electronic device, the size and weight of the electronic device can be reduced.

1. A method for producing a titanium-containing perovskite compound, characterized in that the method comprises a step of reacting titanium oxide produced through a vapor-phase method with at least one element selected from a group of alkaline earth metal compound and Pb compound in an alkaline solution.

2. The method for producing a titanium-containing perovskite compound as claimed in claim 1, wherein primary particles of the titanium-containing perovskite compound have a diameter (D1) that is 50 to 200% the size of primary particles of the titanium oxide serving as a starting material, the size (D1) being determined by converting the specific surface area (S) of the particles obtained by the BET method to the total surface area of spheres in accordance with the following equation (1):
D1=6/ρS (1)
wherein ρ represents a density of the particles and S represents a BET specific surface area.

3. The method for producing a titanium-containing perovskite compound as claimed in claim 1, using ultrafine particles of titanium oxide having a BET specific surface area of 3 to 200 m²/g.

4. The method for producing a titanium-containing perovskite compound as claimed in claim 1, using the titanium oxide produced by oxidizing titanium tetrachloride at high temperature by use of an oxidizing gas.

5. The method for producing a titanium-containing perovskite compound as claimed in claim 4, using the titanium oxide produced by a vapor-phase method is produced by respectively introducing a titanium tetrachloride-containing gas and an oxidizing gas which are heated in advance to 500° C. or higher into a reaction tube at a flow rate of 10 m/sec or more.

6. The method for producing a titanium-containing perovskite compound as claimed in claim 5, using the titanium oxide produced by retaining the titanium tetrachloride-containing gas and the oxidizing gas in the reaction tube for reaction for one second or shorter under a high-temperature condition higher than 600° C.

7. The method for producing a titanium-containing perovskite compound as claimed in claim 6, using the titanium oxide produced under a condition of an average gas flow rate in the reaction tube of 5 m/sec or more.

8. The method for producing a titanium-containing perovskite compound as claimed in claim 1, using the titanium oxide produced by a vapor-phase method is produced by introducing the preheated titanium tetrachloride-containing gas and oxidizing gas into the reaction tube in such a manner that turbulence is generated in the reaction tube.

9. The method for producing a titanium-containing perovskite compound as claimed in claim 8, using the titanium oxide produced by introducing the titanium tetrachloride-containing gas and the oxidizing gas into the reaction tube through a coaxial parallel flow nozzle and the inner tube of the coaxial parallel flow nozzle has an inside diameter of 50 mm or less.

10. The method for producing a titanium-containing perovskite compound as claimed in claim 4, wherein the titanium-tetrachloride-containing gas has a titanium tetrachloride content of 10 to 100%.

11. The method for producing a titanium-containing perovskite compound as claimed in claim 5, wherein each of the titanium tetrachloride-containing gas and the oxidizing gas is heated in advance at 800° C. or higher.

12. The method for producing a titanium-containing perovskite compound as claimed in claim 1, wherein the titanium oxide produced by a vapor-phase method has a mean particle diameter at a 90% cumulative weight on the particle size distribution curve (D₉₀) of 2.2 μm or less.

13. The method for producing a titanium-containing perovskite compound as claimed in claim 1, wherein the titanium oxide produced through a vapor-phase method has a distribution constant n, as calculated from the following Rosin-Rammler equation (2), of 1.7 or more:
R=100 exp(−bDⁿ) (2)
wherein D is a particle diameter; R is the percentage of the number of particles larger than D (particle diameter) with respect to the total number of particles; n is a distribution constant; and b is a reciprocal of particle characteristic constant.

14. The method for producing a titanium-containing perovskite compound as claimed in claim 1, wherein the titanium oxide produced by a vapor-phase method contains anatase-crystal-form titanium oxide.

15. The method for producing a titanium-containing perovskite compound as claimed in claim 1, using an alkaline solution in which a basic compound exists.

16. The method for producing a titanium-containing perovskite compound as claimed in claim 15, wherein the basic compound is selected from ammonium, organic amine and hydroxide of ammonium salt.

17. A titanium-containing perovskite compound, which is produced by a method as claimed in claim 1.

18. The titanium-containing perovskite compound exhibiting ferroelectricity as claimed in claim 17.

19. A dielectric material containing a titanium-containing perovskite compound as claimed in claim 18.

20. A paste containing a titanium-containing perovskite compound as claimed in claim 18.

21. A slurry containing a titanium-containing perovskite compound as claimed in claim 18.

22. A thin-film product containing a titanium-containing perovskite compound as claimed in claim 18.

23. A dielectric ceramics containing a titanium-containing perovskite compound as claimed in claim 18.

24. A pyroelectric ceramics containing a titanium-containing perovskite compound as claimed in claim 18.

25. A piezoelectric ceramics containing a titanium-containing perovskite compound as claimed in claim 18.

26. A capacitor containing a dielectric ceramics as claimed in claim 23.

27. An electronic device containing a thin film product as claimed in claim 22.

28. A sensor containing a thin film product as claimed in claim 22.

29. A dielectric film employing a titanium-containing perovskite compound as claimed in claim 18.

30. A capacitor employing a dielectric film as claimed in claim 29.

31. A ferroelectric memory employing a titanium-containing perovskite compound as claimed in claim 18.

32. A capacitor built in a substrate, which capacitor employs a titanium-containing perovskite compound as claimed in claim 18.
